(19) United States
(12) Patent Application Publication
(10) Pub. No.: US 2026/0089409 A1
(43) Pub. Date: Mar. 26, 2026

(54) IMAGE SENSOR, IMAGING APPARATUS, IMAGING METHOD, AND STORAGE MEDIUM

(71) Applicant: CANON KABUSHIKI KAISHA, Tokyo (JP)

(72) Inventors: TETSU OIKAWA, Kanagawa (JP); SHUNICHI WAKASHIMA, Tokyo (JP)

(21) Appl. No.: 19/329,739

(22) Filed: Sep. 16, 2025

(30) Foreign Application Priority Data
Sep. 24, 2024 (JP) 2024-164821

(51) Int. Cl. H04N 25/771; H04N 23/67; H10F 39/00

(52) U.S. Cl. CPC H04N 25/771; H10F 39/802; H10F 39/8037; H04N 23/672

(57) ABSTRACT

In an image sensor, in which pixels including first and second photoelectric conversion units are arrayed in 2-dimensional form. The pixel includes a first charge storage unit that holds charges photoelectrically converted by the first photoelectric conversion unit for a first accumulation period, a second charge storage unit that holds charges photoelectrically converted by the first photoelectric conversion unit for a second accumulation period different from the first accumulation period, a third charge storage unit that holds charges photoelectrically converted by the second photoelectric conversion unit for the first accumulation period, and a fourth charge storage unit that holds charges photoelectrically converted by the second photoelectric conversion unit for the second accumulation period different from the first accumulation period. In the pixel, the first and third charge storage units are arrayed in peripheral portions in a diagonal direction of the pixel, and the second and fourth charge storage units are arrayed in peripheral portions in another diagonal direction of the pixel. The first or third charge storage units of the pixels at each column are arrayed adjacent to the first or third charge storage units of the pixels at an adjacent column with a boundary line in a column direction in between.

### BACKGROUND

### Field of the Technology

The present disclosure relates to an image sensor, an imaging apparatus, an imaging method, and a storage medium.

### Description of the Related Art

Of electronic shutter schemes used for CMOS image sensors, a global electronic shutter (GS) scheme allows all pixels to be exposed simultaneously, and thus imaging can be executed without motion distortion occurring in a rolling shutter scheme of exposing pixels row by row.

Japanese Patent Application Laid-open No. 2020-108022 discloses a configuration that achieves GS by transferring and storing signal charges generated in accordance with an amount of incident light to charge storage units covered by light-shielding films, and then reading them out row by row.

In this scheme, when complete transfer of signal charges is possible, GS can be achieved without introducing circuit elements that generate noise. However, false signals may occur due to an influence of parasitic light sensitivity (PLS) caused by light leaking into charge storage units.

Japanese Patent Application Laid-open No. 2020-108022 discloses an example in which two charge storage units are provided and an expanded dynamic range is enabled and GS and high dynamic range (HDR) imaging are simultaneously implemented by holding signal charges with different exposure times.

Japanese Patent Application Laid-open No. 2017-55359 discloses an example in which a configuration where each pixel includes two charge storage units is provided, and a photoelectric conversion unit is divided in the horizontal direction and the two charge storage units are used to acquire phase difference information.

Accordingly, a configuration capable of executing focus detection using phase difference information is provided. On the other hand, accuracy of focus detection may deteriorate in a subject from which it is difficult to obtain parallax, such as a pattern in the horizontal direction.

Japanese Patent Application Laid-open No. 2020-141122 discloses an example in which accuracy of focus detection is improved by mixing and arraying pixels in which a division direction of photoelectric conversion units is the horizontal direction (horizontal division pixels) and pixels in which a division direction of photoelectric conversion units is the vertical direction (vertical division pixels).

However, in the techniques disclosed in the above patent literature, for example, it is necessary to open contacts in light-shielding films of the charge storage units and wire control lines. Therefore, PLS is likely to deteriorate.

### SUMMARY

In an image sensor, pixels including first and second photoelectric conversion units are arrayed in 2-dimensional form. The pixel includes a first charge storage unit that holds charges photoelectrically converted by the first photoelectric conversion unit for a first accumulation period, a second charge storage unit that holds charges photoelectrically converted by the first photoelectric conversion unit for a second accumulation period different from the first accumulation period, a third charge storage unit that holds charges photoelectrically converted by the second photoelectric conversion unit for the first accumulation period, and a fourth charge storage unit that holds charges photoelectrically converted by the second photoelectric conversion unit for the second accumulation period different from the first accumulation period. In the pixel, the first and third charge storage units are arrayed in peripheral portions in a diagonal direction of the pixel, and the second and fourth charge storage units are arrayed in peripheral portions in another diagonal direction of the pixel. The first or third charge storage units of the pixels at each column are arrayed adjacent to the first or third charge storage units of the pixels at an adjacent column with a boundary line in a column direction in between.

Further features of the present invention will become apparent from the following description of embodiments with reference to the attached drawings.

### BRIEF DESCRIPTION OF THE DRAWINGS

FIG. 1 is a diagram schematically illustrating an overall configuration example of an image sensor according to an embodiment.

FIG. 2 is a diagram schematically illustrating an equivalent circuit example of a pixel according to the embodiment.

FIG. 3 is a diagram schematically illustrating an example of a division direction of photoelectric conversion units and an array example of charge storage units in the pixel in a range of 2×2 four pixels according to the embodiment.

FIG. 4 is a diagram schematically illustrating an example of a cross-section of the pixel according to the embodiment.

FIG. 5A is a timing chart illustrating an example of an accumulation operation of the pixel according to the embodiment.

FIG. 5B is a timing chart illustrating an example of a reading operation after the accumulation operation of the pixel according to the embodiment.

FIG. 6 is a graph illustrating an example of a relationship between an exposure amount and a signal amount according to the embodiment.

FIG. 7 is a functional block diagram schematically illustrating a configuration example of an imaging apparatus according to the embodiment.

FIG. 8 is a diagram illustrating a correspondence example of the pixel of the image sensor and a pupil intensity distribution according to the embodiment.

FIG. 9 is a diagram schematically illustrating an example of the pupil intensity distribution according to the embodiment.

FIG. 10 is a diagram illustrating an example of correspondence between the image sensor and the pupil intensity distribution according to the embodiment.

FIG. 11 is a diagram illustrating an example of pupil division in an imaging optical system and the image sensor according to the embodiment.

### DESCRIPTION OF THE EMBODIMENTS

Hereinafter, with reference to the accompanying drawings, favorable modes of the present disclosure will be described using Embodiments. In each diagram, the same reference signs are applied to the same members or elements, and duplicate description will be omitted or simplified.

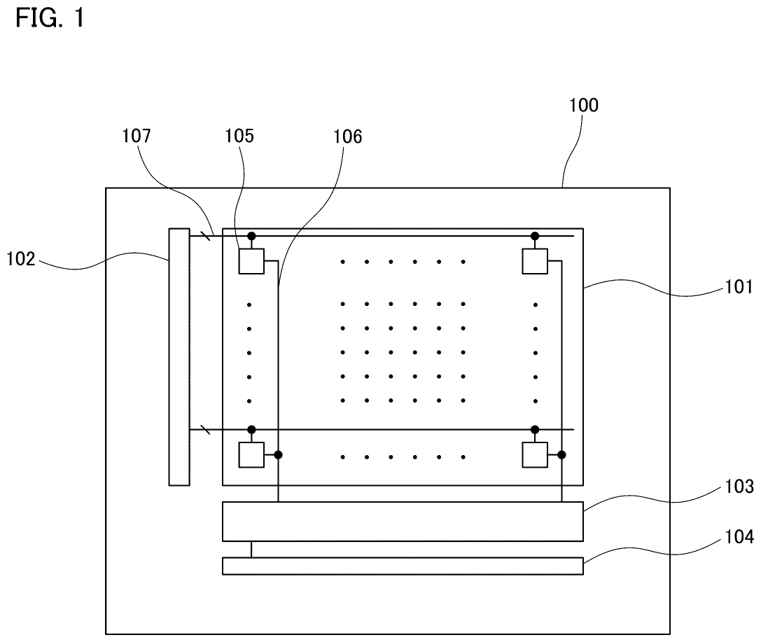

FIG. 1 is a diagram schematically illustrating an overall configuration example of an image sensor 100 according to an embodiment of the present disclosure. The image sensor 100 includes a pixel array unit 101, a vertical selection circuit 102, a column circuit 103, and a horizontal selection circuit 104.

In the pixel array unit 101, the pixels 105 are arrayed in a 2-dimensional array form. Exposure (charge accumulation) is started by applying a reset signal to all the pixels via a pixel control line group 107 and by turning off the reset signal.

Thereafter, the exposure (charge accumulation) ends by applying a transfer signal to an in-pixel charge storage unit to all the pixels via the pixel control line group 107. In this way, timings for starting and ending exposure can be set to be the same for all pixels.

Subsequently, when an output of the vertical selection circuit 102 is supplied to a pixel group at a specific row of pixels via the pixel control line group 107, a phase difference signal and an imaging signal generated in each pixel of the row can be output to each vertical signal line 106. In the present embodiment, one vertical signal line 106 is arrayed per column, but it is also possible to arrange one vertical signal line 106 for every plurality of columns or arrange plurality of vertical signal lines per column.

A signal from each pixel is output to the column circuit 103 via the vertical signal line 106, processes such as noise removal, amplification, and A/D conversion are performed, and then the signals are output to the outside of the image sensor 100 via horizontal signal lines (not illustrated) in order from columns selected by the horizontal selection circuit 104.

By repeating the above operations, the imaging signals and phase difference signals of the pixel group of the 2-dimensional array form of pixels during a simultaneous exposure period of all the pixels can be output from the image sensor 100.

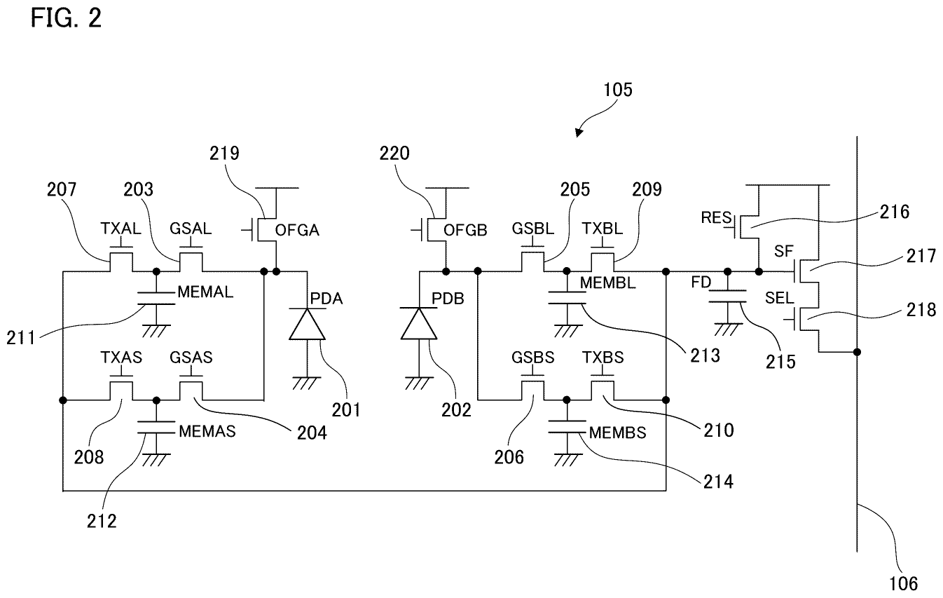

FIG. 2 is a diagram schematically illustrating an equivalent circuit example of the pixel 105 according to the embodiment. In FIG. 2, reference numerals 201 (PDA) and 202 (PDB) denote two photodiodes and are arrayed in one pixel. Here, the photodiodes 201 and 202 function as first and second photoelectric conversion units, respectively. In this way, in the image sensor according to the present embodiment, a plurality of pixels including the first and second photoelectric conversion units are arrayed in a 2-dimensional form.

Reference numerals 203 (GSAL) and 204 (GSAS) denote transistors that transfer signal charges generated by the photodiode 201 to a first charge storage unit 211 (MEMAL) and a second charge storage unit 212 (MEMAS), respectively.

In the present embodiment, the first charge storage unit 211 (MEMAL) and the second charge storage unit 212 (MEMAS) are formed as potential wells below gate electrodes of the transistors 203 (GSAL) and 204 (GSAS), respectively. That is, the gate electrodes of the transistors 203 (GSAL) and 204 (GSAS) correspond to the first charge storage unit 211 (MEMAL) and the second charge storage unit 212 (MEMAS), respectively.

Accordingly, when charges are transferred from the photodiode 201 to the first charge storage unit 211 (MEMAL) and the second charge storage unit 212 (MEMAS), for example, a voltage with a high level is applied to the gate electrodes of the transistors 203 (GSAL) and 204 (GSAS). Accordingly, the charges of the photodiode 201 are transferred by lowering the potential wells below the gate electrodes of the transistors 203 (GSAL) and 204 (GSAS).

Reference numerals 205 (GSBL) and 206 (GSBS) denote transistors that transfer signal charges generated by the photodiode 202 to a third charge storage unit 213 (MEMBL) and a fourth charge storage unit 214 (MEMBS), respectively.

In the present embodiment, the third charge storage unit 213 (MEMBL) and the fourth charge storage unit 214 (MEMBS) are formed as potential wells below the gate electrodes of the transistors 205 (GSBL) and 206 (GSBS). That is, the gate electrodes of the transistors 205 (GSBL) and 206 (GSBS) correspond to the third charge storage unit 213 (MEMBL) and the fourth charge storage unit 214 (MEMBS), respectively.

Accordingly, when charges are transferred from the photodiode 202 to the third charge storage unit 213 (MEMBL) and the fourth charge storage unit 214 (MEMBS), a voltage with a high level is applied to the gate electrodes of the transistors 205 (GSBL) and 206 (GSBS), respectively. Accordingly, the charges of the photodiode 202 are transferred by lowering the potential wells below the gate electrodes of the transistors 205 (GSBL) and 206 (GSBS), respectively.

The first and third charge storage units are units that hold charges photoelectrically converted by the first and second photoelectric conversion units for a first accumulation period. The second and fourth charge storage units are units that hold charges photoelectrically converted by the first and second photoelectric conversion units for a second accumulation period different from the first accumulation period. In the present embodiment, the first accumulation time is longer than the second accumulation time.

Reference numerals 207 (TXAL) and 208 (TXAS) denote transistors that transfer signal charges from the first charge storage unit 211 (MEMAL) and the second charge storage unit 212 (MEMAS) to a charge voltage conversion unit 215 (FD), respectively.

Reference numerals 209 (TXBL) and 210 (TXBS) denote transistors that transfer signal charges from the third charge storage unit 213 (MEMBL) and the fourth charge storage unit 214 (MEMBS) to the charge voltage conversion unit 215, respectively.

Reference numeral 216 (RES) denotes a reset transistor that resets a potential of the charge voltage conversion unit 215. Reference numeral 217 (SF) denotes an amplification transistor that outputs a signal voltage to the vertical signal line 106.

Reference numeral 218 (SEL) denotes a select transistor that receives a selection signal from the vertical selection circuit 102 and selects pixels. Reference numerals 219 (OFGA) and 220 (OFGB) denote discharge transistors that discharge charges from the photodiodes 201 and 202, respectively.

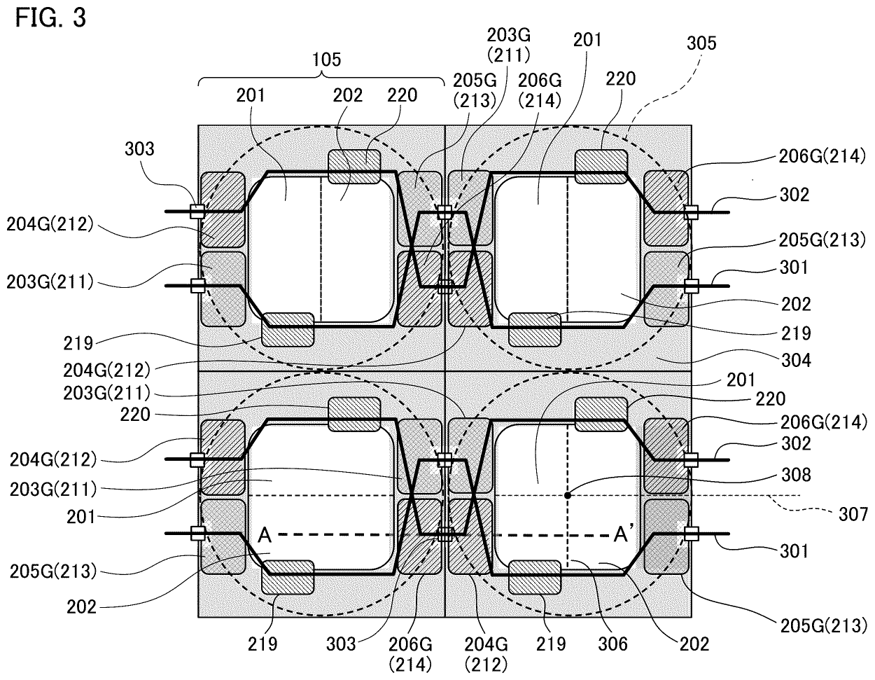

FIG. 3 is a diagram schematically illustrating an example of a division direction of photoelectric conversion units and an array example of charge storage units in the pixel in a range of 2×2 four pixels according to the embodiment. That is, FIG. 3 illustrates an example of the division direction of the photoelectric conversion units of four pixels 105 and an array example of the charge storage units.

In the example illustrated in FIG. 3, of four pixels of 2×2, the photoelectric conversion units of three upper left, upper right, and lower right pixels 105 include two photodiodes 201 and 202 divided in the horizontal direction. The photoelectric conversion unit of one lower left pixel 105 includes two photodiodes 201 and 202 divided in the vertical direction.

Here, a pixel that includes two photodiodes 201 and 202 acquired by dividing the photoelectric conversion unit in the horizontal direction is referred to as a first pixel, and a pixel that includes two photodiodes 201 and 202 acquired by dividing the photoelectric conversion unit in the vertical direction is referred to as a second pixel. A ratio of the number of first pixels to the number of second pixels and a positional relationship between the pixels are not limited to the example illustrated in FIG. 3.

In this way, the plurality of pixels according to the present embodiment includes the first pixels in which the first and second photoelectric conversion units are arrayed side by side in the horizontal direction and the second pixels in which the first and second photoelectric conversion units are arrayed side by side in the vertical direction.

In FIG. 3, reference numerals 203G to 206G denote gate electrodes of the transistors 203 (GSAL), 204 (GSAS), 205 (GSBL), and 206 (GSBS), respectively. Reference numerals 203G to 206G function as first to fourth gate electrodes, respectively.

As described above, in the first to fourth gate electrodes, the first charge storage unit 211 to the fourth charge storage unit 214 are formed. Accordingly, to indicate the correspondence relationship in FIG. 3, the gate electrodes 203G to 206G are referred to as 203G (211), 204G (212), 205G (213), and 206G (214).

In this way, in the present embodiment, first and second gate electrodes transmitting charges of the first photoelectric conversion unit to the first charge storage unit 211 and the second charge storage unit 212 are arrayed above the first charge storage unit 211 and the second charge storage unit 212, respectively.

Third and fourth gate electrodes transmitting charges of the second photoelectric conversion unit to the third charge storage unit 213 and the fourth charge storage unit 214 are arrayed above the third charge storage unit 213 and the fourth charge storage unit 214, respectively.

In FIG. 3, reference numeral 301 denotes a first control line for supplying a common drive signal to the gate electrodes of the transistors 203 (GSAL) and 205 (GSBL) that transfer the charges to the first charge storage unit MEMAL 211 and the third charge storage unit MEMBL 213.

Reference numeral 302 denotes a second control line for supplying a common drive signal to the gate electrodes of the transistors 204 (GSAS) and 206 (GSBS) that transfer the charges to the second charge storage unit MEMAS 212 and the fourth charge storage unit MEMBS 214.

That is, the first control line is commonly connected to the first and third gate electrodes, and the second control line is commonly connected to the second and fourth gate electrodes.

Reference numeral 303 denotes a contact that connects the first control line 301 or the second control line 302 to the gate electrodes of the transistors 205 and 206, and reference numeral 304 denotes a light-shielding film that shields light leaking to the charge storage units. Reference numeral 305 denotes a microlens that efficiently focuses light incident on pixels on the photoelectric conversion units.

In this way, in the present embodiment, the photodiodes 201 and 202 receive light from different exit pupils of the imaging lenses, which are displaced in the horizontal or vertical direction, via the microlens 305 and each generate a pupil division signal. Accordingly, the plurality of photodiodes 201 and 202 can generate two types of image signals (phase difference signals) that have a phase difference in the horizontal or vertical direction. The details will be described below.

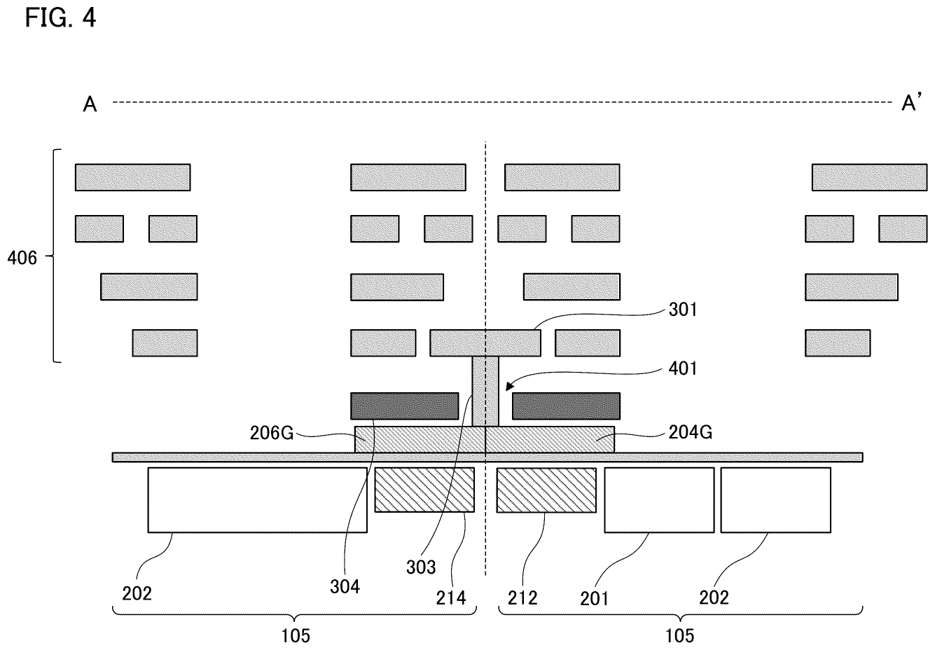

FIG. 4 is a diagram schematically illustrating an example of a cross-section along the line A-A′ of FIG. 3. A metal wiring group 406 is used to supply a constant voltage or a pulse signal and output a pixel signal.

A control line passing above the contact 303 is connected to any gate electrode of the transistors 203 (GSAL), 204 (GSAS), 205 (GSBL), and 206 (GSBS) formed of polysilicon via the contact 303. In the present embodiment, the light-shielding film 304 is formed of, for example, aluminum, but is not limited to aluminum as long as the light-shielding film 304 is formed of a material through which light with a wavelength causing photoelectric conversion in the charge storage unit beneath the gate electrode is not transmitted.

The charge storage unit below each gate electrode of the lower right pixel 105 in FIG. 3 is arrayed as follows when an intersection point 308 of a first straight line 306 dividing the photoelectric conversion unit of the first pixel and a second straight line 307 dividing the photoelectric conversion unit of the second pixel is set as the origin.

That is, in the first quadrant at the upper right of the intersection point 308 that is the origin, the gate electrode of the transistor 206 (GSBS) and the fourth charge storage unit 214 below the gate electrode are arrayed. In the second quadrant at the upper left, the gate electrode of the transistor 203 (GSAL) and the first charge storage unit 211 below the gate electrode are arrayed.

In the third quadrant at the lower left, the gate electrode of the transistor 204 (GSAS) and the second charge storage unit 212 below the gate electrode are arrayed. In the fourth quadrant at the lower right, the gate electrode of transistor 205 (GSBL) and the third charge storage unit 213 below the gate electrode are arrayed.

The first control line 301 is wired such that when the transistor 203 (GSAL) and the transistor 205 (GSBL) of a pixel at a certain column are turned on, the transistor 203 (GSAL) and the transistor 205 (GSBL) of the pixels at an adjacent column of the same row are turned on.

The second control line 302 is wired such that when the transistor 204 (GSAS) and the transistor 206 (GSBS) of a pixel at a certain column are turned on, the transistor 204 (GSAS) and the transistor 206 (GSBS) of the pixels at an adjacent column of the same row are turned on.

As illustrated in FIG. 3, the first charge storage unit 211 and the third charge storage unit 213 are arrayed in peripheral portions in a diagonal direction of each pixel, and the second charge storage unit 212 and the fourth charge storage unit 214 are arrayed in peripheral portions in a diagonal direction of each pixel.

The first charge storage unit 211 and the third charge storage unit 213 of the pixel at each column are arrayed adjacent to the first charge storage unit 211 or the third charge storage unit 213 of the pixels at an adjacent column with a boundary line in a column direction in between.

With such arrayment and wiring, in any of the first and second pixels at the same row, the charge storage unit below the gate electrodes of the transistors simultaneously turned on to transfer charges from the divided photodiodes can be located adjacent to each other. Accordingly, the contact 303 and an opening 401 for wiring the first and second control lines respectively can be shared by the pixels at adjacent columns of the same row.

That is, in the present embodiment, the first and third gate electrodes of adjacent pixels are connected to the first control line by a common contact provided in a common opening of the light-shielding film. The second and fourth gate electrodes of adjacent pixels are connected to the second control line by another common contact provided in another common opening of the light-shielding film.

Accordingly, as illustrated in FIG. 4, the charge storage units below the gate electrodes of the transistors of adjacent pixels at the same row share the opening 401 of the light-shielding film 304 to be combined into a single storage unit, and can be arrayed away from a light-receiving unit. Accordingly, light leaking to the charge storage units via the opening 401 can be minimized, and thus the horizontally divided pixels and the vertically divided pixels can coexist without deteriorating PLS.

Two discharge transistors 219 (OFGA) and 220 (OFGB) can also be arrayed on the side of the center of the photoelectric conversion unit that is different from the division direction of the photoelectric conversion unit, so that one discharge transistor can be adjacent to each of the divided photoelectric conversion units.

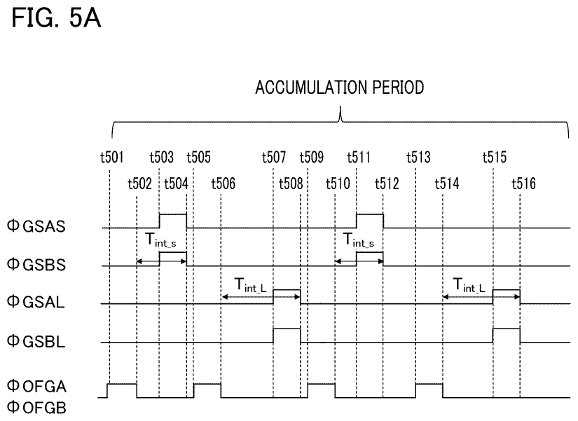

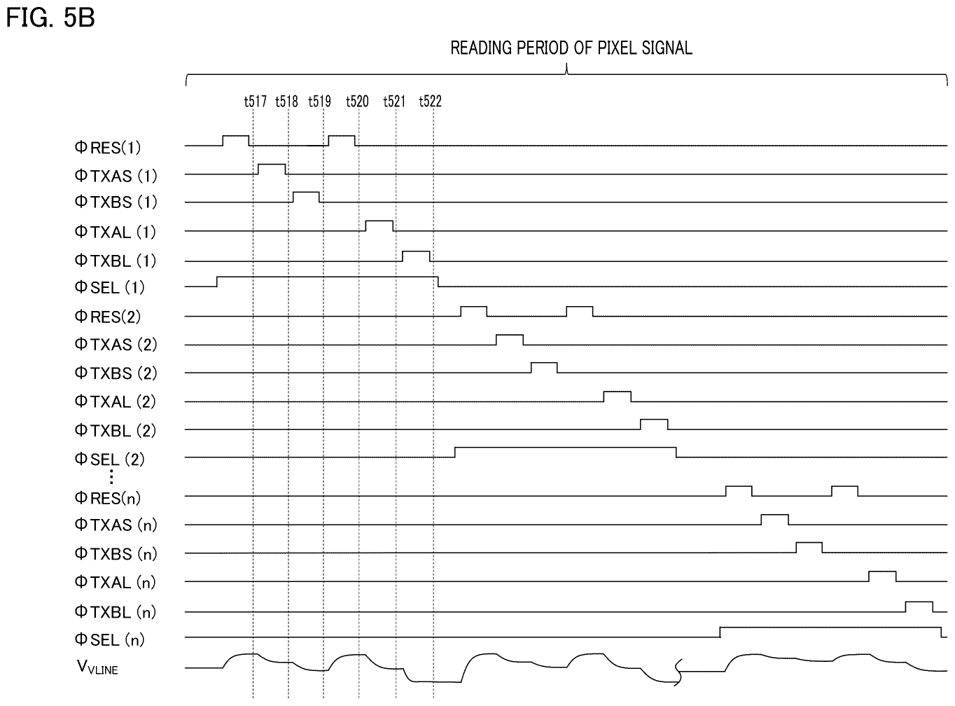

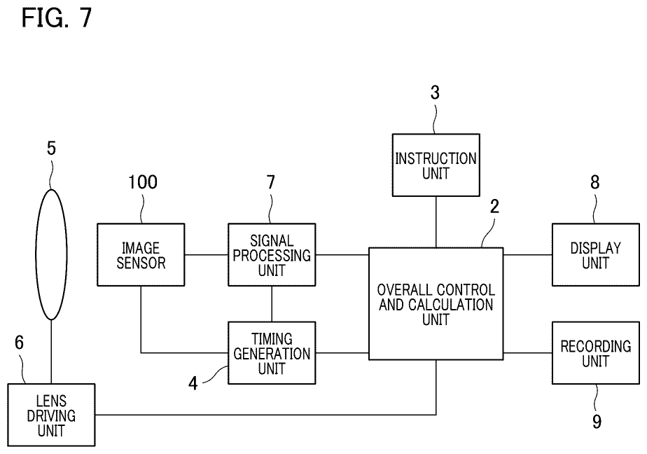

FIG. 5A is a timing chart illustrating an example of an accumulation operation of the pixel according to the embodiment. FIG. 5B is a timing chart illustrating an example of a reading operation after the accumulation operation of the pixel according to the embodiment. Signals illustrated in the timing charts of FIGS. 5A and 5B are supplied from the timing generation unit 4 in FIG. 7, as will be described below. In the present embodiment, a drive timing of each control signal is indicated at (t501).

In FIGS. 5A and 5B, φ represents a drive signal supplied to the gate electrode of the transistor corresponding to a number that follows the transistor. For example, φGSAS corresponds to a signal applied to the gate electrode of the transistor GSAS. A number in ( ) following the number indicates a row number. That is, φRES(1) indicates a drive signal supplied to a gate electrode of a switch RES at a first row.

In the present embodiment, each switch that is an n-channel MOS transistor is turned on (conductive state) when a signal waveform of a drive signal in FIGS. 5A and 5B is high. The switch is turned off (non-conductive state) when the signal waveform is low. An operation of a pixel in the image sensor according to the present embodiment is partitioned into an accumulation period as illustrated in FIG. 5A and a reading period after the accumulation period as illustrated in FIG. 5B.

First, an accumulation operation illustrated in FIG. 5A will be described. It is assumed that drive signals other than the drive signals illustrated in FIG. 5A remain unchanged. The accumulation operation illustrated in FIG. 5A is performed simultaneously in all the pixels of the image sensor, and thus an image to be captured at the same timing for all the pixels can be acquired.

First, at t501 to t502, the discharge transistors 219 (OFGA) and 220 (OFGB) are turned on. Accordingly, the charges remaining in the photoelectric conversion units (the photodiodes 201 and 202) are discharged to fixed potential lines connected to the discharge transistors 219 (OFGA) and 220 (OFGB).

From t502, signal charges photoelectrically converted by the photoelectric conversion units (the photodiodes 201 and 202) start to be accumulated. Subsequently, at t503 to t504, the transistors 204 (GSAS) and 206 (GSBS) are turned on.

Accordingly, the signal charges accumulated for a relatively short accumulation time Tint_S in the divided photoelectric conversion units (the photodiodes 201 and 202) are transferred and held in the second charge storage unit 212 (MEMAS) and the fourth charge storage unit 214 (MEMBS), respectively.

As described above, a time from time t502 at which the discharge transistors 219 (OFGA) and 220 (OFGB) are turned off to time t504 at which the transistors 204 (GSAS) and 206 (GSBS) are turned off is a relatively short accumulation time Tint_S.

Thereafter, at t505 to t506, the discharge transistors 219 (OFGA) and 220 (OFGB) are turned on, and the charges remaining in the photoelectric conversion units (the photodiodes 201 and 202) are discharged.

Subsequently, from t506, the photoelectric conversion units (the photodiodes 201 and 202) start accumulating new signal charges. At t507 to t508, the transistors 203 (GSAL) and 205 (GSBL) are turned on. Then, the signal charges accumulated over a relatively long accumulation time Tint_L in the photodiodes 201 and 202 are transferred and held in the first charge storage unit 211 (MEMAL) and the third charge storage unit 213 (MEMBL), respectively.

In the present embodiment, the one-cycle operation from t501 to t508 is performed once more from t509 to t516. Accordingly, the signal charges transferred and held in the second charge storage unit 212 (MEMAS) and the fourth charge storage unit 214 (MEMBS) at the time point of t512 are signal charges corresponding to an accumulation time of (Tint_S)×2.

The signal charges transferred and held in the first charge storage unit 211 (MEMAL) and the third charge storage unit 213 (MEMBL) at the time point of t516 are signal charges corresponding to an accumulation time of (Tint_L)×2.

Lengths of Tint_S and Tint_L may be other ratios without being limited to the example illustrated in FIG. 5A. In this way, in the present embodiment, two types of signals that are generated by the photodiode 201 and have different exposure times (charge accumulation times) can be acquired for one frame period. Two types of signals that are generated by the photodiode 202 and have different exposure times (charge accumulation times) can be acquired for one frame period.

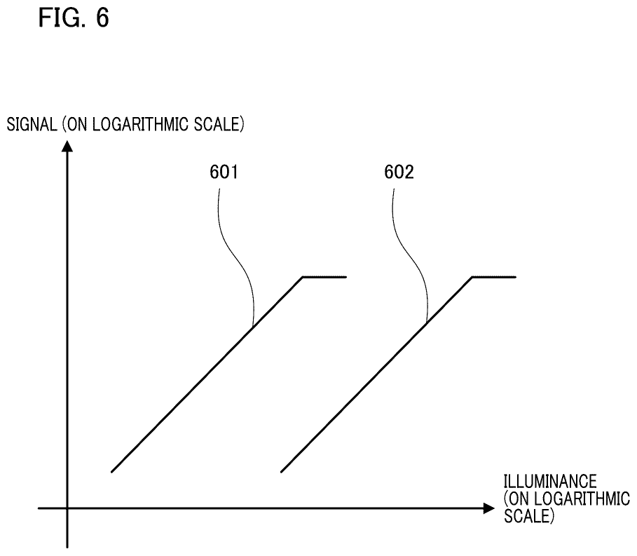

FIG. 6 is a graph illustrating an example of a relationship between an exposure amount and a signal amount according to the embodiment and illustrates a relationship between illuminance (on a logarithmic scale) and a signal level (on a logarithmic scale) in two types of signals having different accumulation times. By correcting the two types of signals obtained in this way in accordance with an accumulation time difference and combining the corrected signals, it is possible to acquire an image with a broad dynamic range.

By changing a ratio of the accumulation time Tint_S to the accumulation time Tint_L, it is possible to vary the dynamic range. In FIGS. 5A and 5B, the one-cycle operation from the accumulation to the transfer indicates a two-cycle operation. During one frame period, the above-cycle operation may be repeated three or more times.

In this way, in the present embodiment, the operations of transferring and holding the signal charges for the relatively short accumulation time Tint_S and the signal charges for the relatively long accumulation time Tint_L within one frame period are repeated by 2 or more cycles. Accordingly, it is possible to reduce an influence of a blinking light source or a rapidly moving subject on an image.

Next, an operation of reading the signal charges transferred and held as described above will be described with reference to FIG. 5B. It is assumed that drive signals other than the drive signals illustrated in FIG. 5B remain unchanged.

A selection signal (for example, φSEL(1)) from the vertical selection circuit 102 is applied to the select transistor 218 (SEL). Accordingly, during a reading period of a pixel group of a selected row (for example, the first row), the select transistor 218 (SEL) is turned on and the charge voltage conversion unit 215 (FD) of each pixel at the selected row is connected to the vertical signal line 106.

At this time, the amplification transistor 217 (SF) in the pixel forms a source follower circuit together with a constant current source (not illustrated) connected to the vertical signal line 106, and a potential of the vertical signal line 106 is a potential relevant to a potential of the charge voltage conversion unit 215 (FD) in the pixel (see V_{VLINE} in FIG. 5B).

By turning on the reset transistor 216 (RES) with φSEL(1) in this state, the potential of the charge voltage conversion unit 215 (FD) is reset. Subsequently, by turning off the reset transistor 216 (RES) to read a reset level voltage VRES_S of the charge voltage conversion unit 215 (FD) at t517. Here, the reset level voltage VRES_S corresponds to a noise component for a short accumulation time.

Subsequently, when the transistor 208 (TXAS) is turned on with φTXAS(1) and the signal charges held in the second charge storage unit 212 (MEMAS) are transferred to the charge voltage conversion unit 215 (FD), a change in voltage in a potential of the vertical signal line 106 occurs in accordance with an amount of charges. At t518, a voltage level VA_S at that time is read. Here, the voltage level VA_S corresponds to signal charges for a short accumulation time in the photodiode 201.

Subsequently, the transistor 210 (TXBS) is turned on with φTXAB(1). Accordingly, the signal charges held in the fourth charge storage unit 214 (MEMBS) are transferred to the charge voltage conversion unit 215 (FD), the signal charges are added to the signal charges already present in the charge voltage conversion unit 215 (FD), and a voltage level VA+B_S at that time is read at t519. Here, the voltage level VA+B_S corresponds to signal charges to which the signal charges for a short accumulation time in the photodiodes 201 and 202 are added.

By turning on the reset transistor 216 (RES) with φRES(1) again after t519, a voltage of the charge voltage conversion unit 215 (FD) is reset and a voltage level VRES_L is read at t520. At this time, the voltage level VRES_L corresponds to a noise component for a long accumulation time.

Subsequently, the transistor 207 (TXAL) is turned on with φTXAL(1), the charges held in the first charge storage unit 211 (MEMAL) are transferred to the charge voltage conversion unit 215 (FD), and a voltage level VA_L is read at t521. Here, the voltage level VA_L corresponds to signal charges for a long accumulation time in the photodiode 201.

Similarly, the transistor 209 (TXBL) is turned on with φTXBL(1). Accordingly, the charges held in the third charge storage unit 213 (MEMBL) are transferred to the charge voltage conversion unit 215 (FD), the charges are added to the signal charges already present in the charge voltage conversion unit 215 (FD), and a voltage level VA+B_L is read at t522.

Here, the voltage level VA+B_L corresponds to the signal charges to which the signal charges for a long accumulation time in the photodiodes 201 and 202 are added. An operation until t522 of FIG. 5B is a reading operation at the first row and is also repeated sequentially at subsequent rows after time t522 to perform the reading operation sequentially on all the pixels.

Based on the signals obtained in this way, a signal processing unit 7 in FIG. 7 to be described below calculates |VA_S-VRES_S|, and thus a signal component acquired by removing a noise component from the amount of charges held in the second charge storage unit 212 (MEMAS) can be obtained. Here, |VA_S-VBES_S| corresponds to a signal component acquired by removing a noise component from the signal charges for a short accumulation time in the photodiode 201.

The signal processing unit 7 can calculate |VA+B_S-VRES_S| to obtain a signal component acquired by removing a noise component from signals to which the amount of charges held in the second charge storage unit 212 (MEMAS) and the fourth charge storage unit 214 (MEMBS) are added. That is, |VA+B_S-VRES_S| corresponds to signal components acquired by removing noise components from the signal charges to which signal charges for a short accumulation time in the photodiodes 201 and 202 are added.

Similarly, by calculating |VA_L-VRES_L|, it is possible to obtain a signal component acquired by removing a noise component from an amount of charges held in the first charge storage unit 211 (MEMAL). Here, |VA_L-VRES_L| corresponds to a signal component acquired by removing a noise component from the signal charges for a long accumulation time in the photodiode 201.

The signal processing unit 7 can calculate |VA+B_L-VRES_L| to obtain a signal component acquired by removing a noise component from signals to which the amount of charges held in the first charge storage unit 211 (MEMAL) and the third charge storage unit 213 (MEMBL) are added. That is, |VA+B_L-VRES_L| corresponds to signal components acquired by removing noise components from the signal charges to which signal charges for a long accumulation time in the photodiodes 201 and 202 are added.

The signal processing unit 7 can perform the above reading and calculation to cancel noise remaining immediately after resetting the charge voltage conversion unit 215 (FD) or an offset variation occurring due to a difference in a threshold voltage of the amplification transistor 217 for each pixel.

By sequentially repeating the operations on all the rows, it is possible to calculate |VA_S-VRES_S|, |VA+B_S-VRES_S|, |VA_L-VRES_L|, and |VA+B_L-VRES_L| on all the pixels to acquire four types of images.

That is, the signal processing unit 7 can acquire a first image corresponding to the signal component for the short accumulation time in the photodiode 201 and a second image corresponding to the signal component of the added charges to which the charges for the short accumulation time in the photodiodes 201 and 202 are added.

The signal processing unit 7 can acquire a third image corresponding to the signal component for the long accumulation time in the photodiode 201 and a fourth image corresponding to the signal component of the added charges to which the charges for the long accumulation time in the photodiodes 201 and 202 are added. Noise is removed from the first to fourth images.

According to the present embodiment, by arraying the charge storage units and performing the exposure and reading operations as described above, it is possible to acquire the images for the relatively short accumulation time and the images for the relatively long accumulation time of the same timing in the photoelectric conversion units (photodiodes 201 and 202) of all the pixels.

Further, without involving degradation in PLS, it is possible to acquire the first to fourth images respectively from first pixels having the photodiodes divided in the horizontal direction and second pixels having photodiodes divided in the vertical direction.

The signal processing unit 7 can generate, for example, a display combined image signal with a broad dynamic range by combining the second and fourth images acquired from all the pixels. The display combined image signal acquired in this way can be displayed by a display unit 8 in FIG. 7 to be described below. Further, the display combined image signal can also be recorded by the recording unit 9 illustrated in FIG. 7.

That is, in the imaging apparatus (imaging method) according to the present embodiment, the second image generated based on the charges held individually in the first and third charge storage units is combined with the fourth image generated based on the charges held individually in the second and fourth charge storage units. The combining process is implemented by causing a CPU serving as a computer of an overall control and calculation unit in FIG. 7 to execute a computer program stored in a memory.

On the other hand, the signal processing unit 7 can acquire a fifth image signal for a short accumulation time formed by a group of the photodiodes 202, for example, by subtracting the first image from the second image. Also, by subtracting the third image from the fourth image, a sixth image signal for a long accumulation time formed by the group of photodiodes 202 can be generated.

Since the first and fifth images have a parallax (phase difference), the signal processing unit 7 can calculate a distance DS1 to a subject based on a phase difference between the first and fifth images. Similarly, since the third and sixth images also have a parallax (phase difference), the signal processing unit 7 can calculate a distance DL1 to a subject based on a phase difference between the third and sixth images.

Further, the signal processing unit 7 may calculate an average distance DAV1 to the subject, for example, by performing a weighted average of the distances DS1 and DL1 based on each reliability. In this case, a weight of distance DL1 may be relatively increased for a relatively dark subject, and a weight of distance DS1 may be relatively increased for a relatively bright subject.

Distances corresponding to the above distances DS1 and DL1 obtained from the first pixels in which the photodiodes 201 and 202 are divided in the horizontal direction may be referred to as distances DSH1 and DLH1, respectively.

Similarly, the distances corresponding to the above distances DS1 and DL1 obtained from the second pixels in which the photodiodes 201 and 202 are divided in the vertical direction may be referred to as distances DSV1 and DLV1, respectively.

The signal processing unit 7 may calculate an average distance DAV2 to a subject by performing a weighted average of the distances DSV1 and DLV1 based on each reliability. Accordingly, it is possible to accurately calculate a distance even to, for example, a subject with horizontal stripes. In this case, a weight of the distance DLV1 may be relatively increased for a relatively dark subject, and a weight of the distance DSV1 may be relatively increased for a relatively bright subject.

The above-described average distance DAV1 obtained from the plurality of first pixels in which the photodiodes 201 and 202 are divided in the horizontal direction, and the above-described average distance DAV2 obtained from the plurality of second pixels may be weighted and averaged based on each reliability. Accordingly, a final distance DVF may be calculated.

At that time, the signal processing unit 7 may perform image recognition to determine a ratio of vertical stripes to horizontal stripes of a subject. When there are many vertical stripes, the weight of DAV1 may be relatively increased. When there are many horizontal stripes, the weight of DAV2 may be relatively increased for calculation.

As described above, in the present embodiment, the signal processing unit 7 calculates a distance to a subject based on the charges photoelectrically converted for the first accumulation period and the charges photoelectrically converted for the second accumulation period, respectively, in the first and second photoelectric conversion units.

Next, an example of the imaging apparatus in which the image sensor according to the above-described embodiment is used will be described. FIG. 7 is a functional block diagram schematically illustrating a configuration example of the imaging apparatus according to the embodiment. Some of functional blocks illustrated in FIG. 7 are implemented by causing a CPU or the like serving as a computer (not illustrated) included in the imaging apparatus to execute a computer program stored in a memory serving as a storage medium (not illustrated).

However, some or all of the functional blocks may be implemented with hardware. As the hardware, a dedicated circuit (ASIC), a processor (a reconfigurable processor or a DSP), or the like can be used. The functional blocks illustrated in FIG. 7 may not be housed in the same casing or may be configured with separate devices connected to each other via signal lines.

As illustrated in FIG. 7, the imaging apparatus according to the present embodiment includes an image sensor 100, an overall control and calculation unit 2, an instruction unit 3, a timing generation unit 4, an imaging lens unit 5, a lens driving unit 6, a signal processing unit 7, a display unit 8, and a recording unit 9.

The imaging lens unit 5 forms an optical image of a subject on the light reception surface of the image sensor 100. Although the imaging lens unit 5 is illustrated as a single lens in FIG. 7, the imaging lens unit 5 may include multiple lenses such as a focus lens and a zoom lens and an aperture, and may be mounted to be detachable from the main body of the imaging apparatus or integrally configured in the main body.

The image sensor 100 has a configuration such as the above-described embodiment, and converts light incident on the light reception surface of the image sensor 100 via the imaging lens unit 5 into an electrical signal and outputs the converted electrical signal.

The overall control and calculation unit 2 contains a CPU serving as a computer and a memory that stores a computer program and controls each unit of the imaging apparatus by causing the CPU to execute the computer program.

The above-described calculation process for focus detection is performed using the image signal processed by the signal processing unit 7. Further, a calculation process for exposure control such as an aperture and an accumulation time or predetermined signal processing such as development and compression for generating an image for recording and display is performed based on the image signal.

The lens driving unit 6 drives the imaging lens unit 5. Focus control, zoom control, aperture control, and the like are performed on the imaging lens unit 5 in accordance with a control signal from the overall control and calculation unit 2.

The instruction unit 3 receives an input such as an imaging execution instruction input from the outside in response to an operation of a user or the like, a driving mode setting of the imaging apparatus, another various types of setting or selection and transmits the input to the overall control and calculation unit 2. The timing generation unit 4 generates a timing signal for driving the image sensor 100 and the signal processing unit 7 in accordance with a control signal from the overall control and calculation unit 2.

The display unit 8 displays information such as a preview image, a reproduction image, and a drive mode of the imaging apparatus. The recording unit 9 is provided with a recording medium (not illustrated), so that an image signal to be recorded is stored. Examples of recording medium include a flash memory. The recording medium may be mounted to be detachable from the recording unit 9 or may be embedded in the recording unit 9.

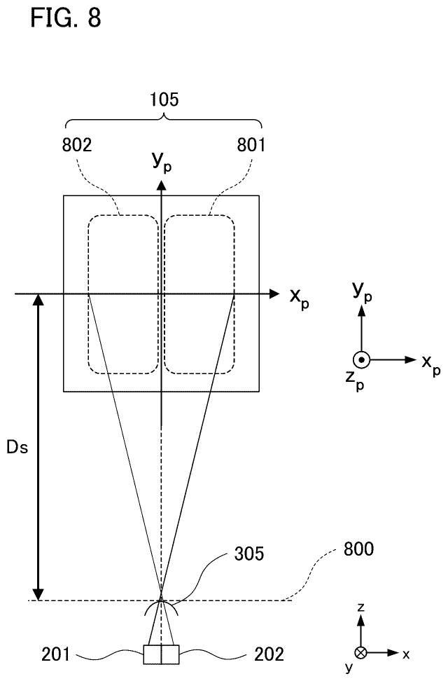

Next, an operation of calculating a defocus amount in the overall control and calculation unit 2 to derive a defocus amount from a pupil division signal will be described with reference to FIGS. 8 to 11. An operation of calculating the defocus amount from a phase difference signal in the horizontal direction and an operation of calculating a defocus amount from a phase difference signal in the vertical direction are the same in principle. Therefore, the calculation operation from the phase difference signal in the horizontal direction will be described.

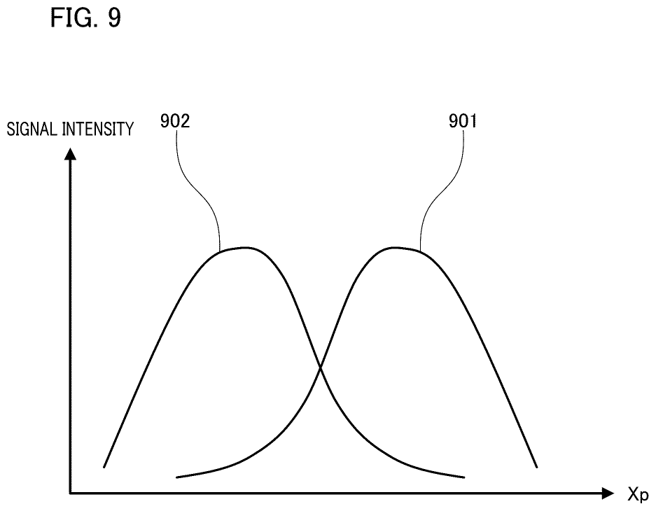

FIG. 8 is a diagram illustrating a correspondence example of the pixel 105 of the image sensor and a pupil intensity distribution according to the present embodiment. FIG. 9 is a diagram schematically illustrating an example of the pupil intensity distribution according to the present embodiment. FIG. 8 illustrates an example of a horizontal cross-section of the pixel in which a dividing direction of the photodiodes 201 and 202 is the horizontal direction (x-axis direction) and a pupil plane of the imaging lens unit 5 at a position away at a distance Ds in the negative direction of the z axis (optical axis) from a light reception surface 800 of the image sensor 100.

The pupil plane of the imaging lens unit 5 and the light reception surface (second surface) of the image sensor have a substantially conjugate relationship via the microlens 305. Therefore, a light flux passing through a partial pupil region 801 is mostly received by the divided photodiode 201.

The light flux passing through a partial pupil region 802 is mostly received by photodiode 202. Signal charges photoelectrically converted near the center between photodiodes 201 and 202 probabilistically move to a potential well of either photodiode.

Therefore, at a boundary between the partial pupil regions 801 and 802, a signal intensity of a pupil intensity distribution in the photodiodes 201 and 202 is gradually switched as xp coordinates increase. The xp-direction dependency of the pupil intensity distribution takes a form exemplified in FIG. 9. Here, the pupil intensity distribution corresponding to the photodiode 201 is referred to as a first pupil intensity distribution 901, and the pupil intensity distribution corresponding to the photodiode 202 is referred to as a second pupil intensity distribution 902.

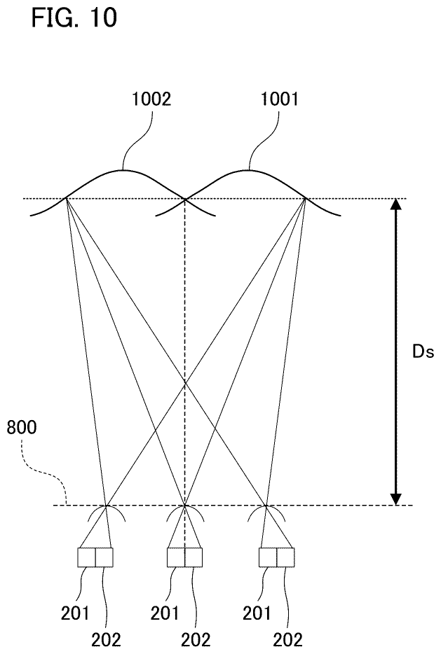

FIG. 10 is a diagram illustrating an example of correspondence between the image sensor and the pupil intensity distribution according to the embodiment. As illustrated in FIG. 10, in the image sensor 100 according to the present embodiment, an optical axis of the microlens 305 is arrayed to shift from the center of the pixel depending on an image height.

That is, as the image height increases, the optical axis of each microlens is arranged to be decentered toward the center side of the light reception surface of the image sensor relative to the center of each pixel. When the imaging apparatus includes a camera movement prevention mechanism, the center of the light reception surface of the image sensor and the optical axis of the imaging optical system may slightly change due to driving of the optical system or the image sensor by the camera movement prevention mechanism, but such change can be ignored.

With the configuration illustrated in FIG. 10, the first pupil intensity distribution 901 and the second pupil intensity distribution 902 received by the photodiodes 201 and 202 of each pixel become approximately equivalent, even when the image height in the image sensor 100 is different.

Hereinafter, the first pupil intensity distribution 901 and the second pupil intensity distribution 902 are referred to as a “sensor incidence pupil” of the image sensor 100, and the distance Ds is referred to as a “sensor pupil distance” of the image sensor 100. It is not necessary for all the pixels to share a single incidence pupil distance. For example, the pixels may be configured such that incidence pupil distances are approximately aligned up to 80% of the image height, or the pixels are intentionally configured so that each row or each detection region has a different incidence pupil distance.

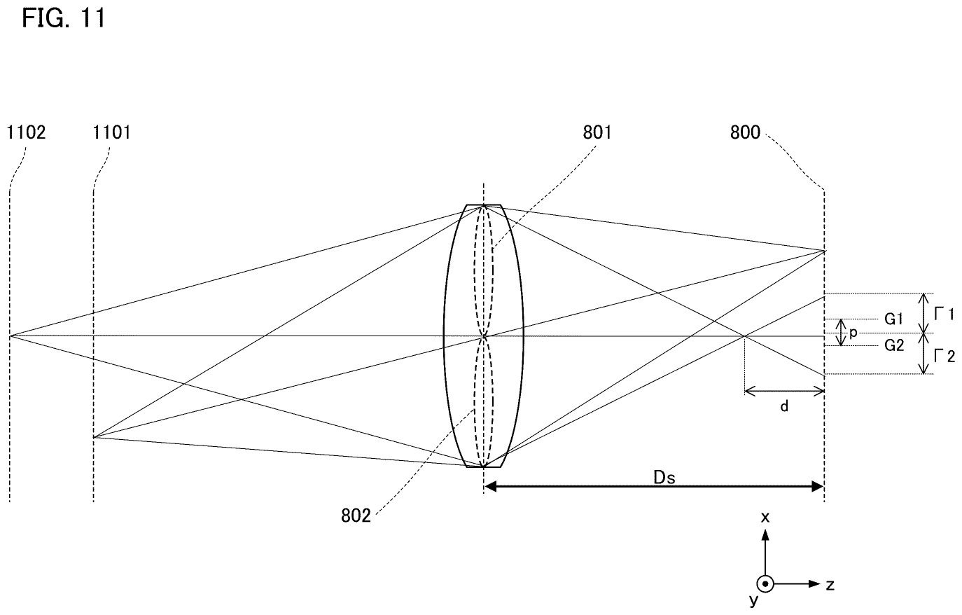

FIG. 11 is a diagram illustrating an example of pupil division in the imaging optical system and the image sensor according to the embodiment and illustrates a schematic relationship between a defocus amount and an image shift amount between parallax images. The light reception surface 800 corresponds to a light reception surface of the image sensor according to the present embodiment. As in FIG. 8, an exit pupil of the imaging optical system is divided into two regions, partial pupil regions 801 and 802.

A defocus amount d is defined such that a distance between an image forming position of a subject and an imaging plane is magnitude |d|, a front-focus state in which an image forming position of the subject is on the subject side of the imaging plane is given a negative sign (where d<0), and a back-focus state in which the image forming position of the subject is on the opposite side of the imaging plane from the subject is given a positive sign (where d>0).

An in-focus state in which an image forming position of a subject is on the imaging plane is d=0. FIG. 11 illustrates an example in which a subject 1101 is in an in-focus state (where d=0) and an example of a subject 1102 is in the front-focus state (where d<0). The front-focus state (where d<0) and the back-focus state (where d>0) are collectively referred to as a defocus state (where |d|>0).

In the front-focus state (where d<0), of a light flux from the subject 1102, a light flux passing through the partial pupil region 801 converges once, then spreads with a width Γ1 (or Γ2) centered on a centroid position G1 (or G2) of the light flux, and forms a blurred image on the light reception surface 800. This blurred image is received by the photodiodes 201 and 202, and parallax images (phase difference signals) are generated.

Accordingly, in the generated parallax images, the subject 1102 is formed as a blurred subject image of the width Γ1 (or Γ2) centered on the centroid position G1 (or G2). The blur width Γ1 (or Γ2) of the subject image increases approximately in proportion to the magnitude of the defocus amount |d|.

Similarly, magnitude |p| of the image shift amount p (=G2−G1) between the parallax images of the subject image also increases approximately in proportion to the magnitude |d| of the defocus amount d. In the back-focus state (where d>0), the same applies although an image shift direction of the subject image between the parallax images is opposite to that in the front-focus state.

In the in-focus state (where d=0), the centroid positions of the subject images in the parallax images match (where p=0), and no image shift occurs. Accordingly, in two phase difference signals obtained using the signals from the photodiodes 201 and 202, an image shift amount in the x-direction between the two phase difference signals increases as magnitude of the defocus amount of the parallax images increases.

Based on this relationship, by performing a correlation operation on the x-direction image shift amount between the parallax images and converting the calculated shift amount into a defocus amount, focus detection can be performed in accordance with a phase-difference detection scheme.

While the present disclosure has been described with reference to embodiments, it is to be understood that the disclosure is not limited to the disclosed embodiments. The scope of the following claims is to be accorded the broadest interpretation so as to encompass all such modifications and equivalent structures and functions.

In addition, as a part or the whole of the control according to the embodiments, a computer program realizing the function of the embodiments described above may be supplied to the imaging apparatus or the like through a network or various storage media. Then, a computer (or a CPU, an MPU, or the like) of the imaging apparatus or the like may be configured to read and execute the program. In such a case, the program and the storage medium storing the program configure the present invention.

In addition, the present disclosure includes those realized using at least one processor or circuit configured to perform functions of the embodiments explained above. For example, a plurality of processors may be used for distribution processing to perform functions of the embodiments explained above.

This application claims the benefit of Japanese Patent Application No. 2024-164821, filed on Sep. 24, 2024, which is hereby incorporated by reference herein in its entirety.

What is claimed is:

1. An image sensor in which pixels including first and second photoelectric conversion units are arrayed in 2-dimensional form,
wherein the pixel includes a first charge storage unit that holds charges photoelectrically converted by the first photoelectric conversion unit for a first accumulation period, a second charge storage unit that holds charges photoelectrically converted by the first photoelectric conversion unit for a second accumulation period different from the first accumulation period, a third charge storage unit that holds charges photoelectrically converted by the second photoelectric conversion unit for the first accumulation period, and a fourth charge storage unit that holds charges photoelectrically converted by the second photoelectric conversion unit for the second accumulation period different from the first accumulation period,
wherein, in the pixel, the first and third charge storage units are arrayed in peripheral portions in a diagonal direction of the pixel, and the second and fourth charge storage units are arrayed in peripheral portions in another diagonal direction of the pixel, and
wherein the first or third charge storage units of the pixels at each column are arrayed adjacent to the first or third charge storage units of the pixels at an adjacent column with a boundary line in a column direction in between.

2. The image sensor according to claim 1, wherein the pixels include a first pixel in which the first and second photoelectric conversion units are arrayed side by side in a horizontal direction and a second pixel in which the first and second photoelectric conversion units are arrayed side by side in a vertical direction.

3. The image sensor according to claim 1,
wherein first and second gate electrodes transferring the charges of the first photoelectric conversion unit to the first and second charge storage units are arrayed above the first and second charge storage units, respectively, and
wherein third and fourth gate electrodes transferring the charges of the second photoelectric conversion unit to the third and fourth charge storage units are arrayed above the third and fourth charge storage units, respectively.

4. The image sensor according to claim 3, further comprising:
a first control line commonly connecting the first and third gate electrodes, and
a second control line commonly connecting the second and fourth gate electrodes.

5. The image sensor according to claim 4,
wherein the first and third gate electrodes of the adjacent pixels are connected to the first control line by a common contact provided in a common opening of a light-shielding film, and
wherein the second and fourth gate electrodes of the adjacent pixels are connected to the second control line by another common contact provided in another common opening of the light-shielding film.

6. An imaging apparatus in which the image sensor according to claim 1 is used, the imaging apparatus comprising:
at least one processor or circuit configured to function as a signal processing unit configured to combine a second image generated based on charges held in the first and third charge storage units and a fourth image generated based on charges held in the second and fourth charge storage units.

7. The imaging apparatus according to claim 6, wherein the signal processing unit is configured to calculate a distance to a subject based on charges photoelectrically converted for the first accumulation period in each of the first and second photoelectric conversion units.

8. An imaging method using an image sensor,
wherein, in the image sensor, pixels including first and second photoelectric conversion units are arrayed in 2-dimensional form,
wherein the pixel includes a first charge storage unit that holds charges photoelectrically converted by the first photoelectric conversion unit for a first accumulation period, a second charge storage unit that holds charges photoelectrically converted by the first photoelectric conversion unit for a second accumulation period different from the first accumulation period, a third charge storage unit that holds charges photoelectrically converted by the second photoelectric conversion unit for the first accumulation period, and a fourth charge storage unit that holds charges photoelectrically converted by the second photoelectric conversion unit for the second accumulation period different from the first accumulation period,
wherein, in the pixel, the first and third charge storage units are arrayed in peripheral portions in a diagonal direction of the pixel, and the second and fourth charge storage units are arrayed in peripheral portions in another diagonal direction of the pixel,
wherein the first or third charge storage units of the pixels at each column are arrayed adjacent to the first or third charge storage units of the pixels at an adjacent column with a boundary line in a column direction in between, and
wherein a second image generated based on charges held in the first and third charge storage units and a fourth image generated based on charges held in the second and fourth charge storage units are combined.

9. A non-transitory computer-readable storage medium storing a computer program for imaging using an image sensor,
wherein, in the image sensor, pixels including first and second photoelectric conversion units are arrayed in 2-dimensional form,
wherein the pixel includes a first charge storage unit that holds charges photoelectrically converted by the first photoelectric conversion unit for a first accumulation period, a second charge storage unit that holds charges photoelectrically converted by the first photoelectric conversion unit for a second accumulation period different from the first accumulation period, a third charge storage unit that holds charges photoelectrically converted by the second photoelectric conversion unit for the first accumulation period, and a fourth charge storage unit that holds charges photoelectrically converted by the second photoelectric conversion unit for the second accumulation period different from the first accumulation period,
wherein, in the pixel, the first and third charge storage units are arrayed in peripheral portions in a diagonal direction of the pixel, and the second and fourth charge storage units are arrayed in peripheral portions in another diagonal direction of the pixel,
wherein the first or third charge storage units of the pixels at each column are arrayed adjacent to the first or third charge storage units of the pixels at an adjacent column with a boundary line in a column direction in between,
wherein the computer program includes instructions for executing a following process:
to combine a second image generated based on charges held in the first and third charge storage units and a fourth image generated based on charges held in the second and fourth charge storage units.
